(19) United States
(12) Patent Application Publication
(10) Pub. No.: US 2025/0286363 A1
(43) Pub. Date: Sep. 11, 2025

(54) METHODS FOR IDENTIFYING SHORT-CIRCUITS IN SAMPLING ELEMENTS OF BATTERY MANAGEMENT SYSTEMS (BMS) AND PROTECTING THE SAME

(71) Applicant: Lian Zheng Electronics (Shenzhen) Co., Ltd., Shenzhen (CN)

(72) Inventors: Zicheng Feng, Shenzhen (CN); Guojian Li, Shenzhen (CN); Hu Qin, Shenzhen (CN)

(21) Appl. No.: 19/070,597

(22) Filed: Mar. 5, 2025

(30) Foreign Application Priority Data
Mar. 6, 2024 (CN) 202410257659.9

(51) Int. Cl. H02H 5/04; G01K 3/00; G01K 3/10; G01K 7/22; G01R 31/382; G01R 31/52; H02J 7/00

(52) U.S. Cl. CPC H02H 5/042; G01K 3/005; G01K 3/10; G01K 7/22; G01R 31/382; G01R 31/52; H02J 7/00304

(57) ABSTRACT

A short circuit identification method is provided for a sampling element of a battery management system. A temperature sensor is disposed in a battery management system to monitor a temperature of a discharge transistor, and the method includes: obtaining the temperature of the discharge transistor by using the temperature sensor, and calculating a temperature difference of the discharge transistor in a preset duration; comparing a discharge current obtained by using a sampling element with a preset current threshold; and determining that the sampling element is short-circuited. In embodiments of the present application, the temperature sensor is used to monitor the temperature change rate of the discharge transistor in the BMS system, it can be detected that only one sampling element has a short-circuit fault with reference to the discharge current obtained by the sampling element, and corresponding protection measures are taken, so that the BMS system runs safely and stably.

### CROSS-REFERENCE TO RELATED APPLICATION

This application claims priority to Chinese Patent Application No. CN 202410257659.9, filed on Mar. 6, 2024, the content of which is hereby incorporated herein by reference in its entirety.

### TECHNICAL FIELD

The present inventive concept generally relates to the field of battery management technologies, and in particular, to short circuit identification and protection methods for a sampling element of a battery management system.

### BACKGROUND

A battery management system (BMS) can closely monitor, control, and allocate reliable charging and discharging of an entire battery system throughout its service life. The battery management system generally monitors an operating current by using a sampling element and takes measures to protect the battery system upon detecting an abnormality. If a short-circuit fault occurs to the sampling element (for example, a sampling resistor and a current sensor such as a Hall current sensor), it will cause the management system to obtain incorrect operating current data, and treat the abnormality as normal, thereby failing to timely detect a potential harm and take corresponding protection measures. How to detect the short-circuit fault of the sampling element is a technical problem to be resolved by the battery management system.

An existing solution is generally to add a same current sampling element. When sampling data of the two elements is contradictory, it is determined that there is a sampling element fault. However, this solution requires hardware redundancy design, which not only extends development time but also increases production costs.

### SUMMARY

Therefore, some embodiments of the present inventive concept attempt to address the foregoing defect in the conventional technology, and provide a short circuit identification method for a sampling element of a battery management system, where a temperature sensor is disposed in the battery management system to monitor a temperature of a discharge transistor. The method includes:
obtaining the temperature of the discharge transistor by using the temperature sensor, and calculating a temperature difference of the discharge transistor in a preset duration;
in response to determining that the temperature difference is greater than a preset temperature difference threshold, comparing a discharge current obtained by using a sampling element with a preset current threshold; and
in response to determining that the discharge current is less than the preset current threshold, determining that the sampling element is short-circuited.

According to some embodiments of the present inventive concept, the temperature sensor is a thermistor.

According to some embodiments of the present inventive concept, the sampling element is a sampling resistor or a Hall current sensor.

According to some embodiments of the present inventive concept, the preset temperature difference threshold is 4 degrees Celsius or 8 degrees Celsius.

According to some embodiments of the present inventive concept, the preset temperature difference threshold is 4 degrees Celsius, and the preset current threshold is 20 Amperes or 10 Amperes.

According to some embodiments of the present inventive concept, the preset temperature difference threshold is 8 degrees Celsius, and the preset current threshold is 40 Amperes, 20 Amperes, or 10 Amperes.

According to some embodiments of the present inventive concept, the preset duration is 10 seconds, or 20 seconds, or 30 seconds.

According to a second aspect of the present inventive concept, a short circuit protection method for a sampling element of a battery management system is provided, including: in response to identifying, in the short circuit identification method for a sampling element of a battery management system according to any one of foregoing embodiments, that the sampling element is short-circuited, performing circuit protection by turning off the discharge transistor of the battery management system.

According to some embodiments of the second aspect of the present inventive concept, the circuit protection method further includes: turning off a high-current charging transistor, a float charging switch, and a protection charging switch of the battery management system, burning out a controllable fuse, and entering a sleep mode.

According to some embodiments of the second aspect of the present inventive concept, the circuit protection method further includes: turning on the discharge transistor in response to determining that the discharge transistor is turned off and a temperature change rate is 0 degrees Celsius every 30 S for 30 minutes.

In some embodiments of the present inventive concept, the temperature sensor is used to monitor the temperature change rate of the discharge transistor in the BMS system, it can be detected that only one sampling element has a short-circuit fault with reference to the discharge current obtained by the sampling element, and corresponding protection measures are taken, so that the BMS system runs safely and stably.

### BRIEF DESCRIPTION OF THE DRAWINGS

The following further describes the embodiments of the present inventive concept with reference to the accompanying drawings.

FIG. 1 is a schematic diagram of an example circuit of an existing battery management system (BMS).

FIG. 2 is a diagram of a temperature change rate of a discharge transistor at different discharge currents.

FIG. 3 is a schematic diagram of a BMS circuit with an additional temperature sensor in accordance with some embodiments of the present inventive concept.

FIG. 4 is a schematic flowchart of protecting a BMS system after a sampling element is short-circuited according to some embodiments of the present inventive concept.

FIG. 5 is a schematic flowchart of protecting a BMS system after a sampling element is short-circuited according some embodiments of the present inventive concept.

### DETAILED DESCRIPTION

To make the objectives, technical solutions, and advantages of the present inventive concept clearer, the following further describes the present inventive concept in detail through the embodiments with reference to the accompanying drawings. It should be understood that the embodiments described herein are merely used to explain the present inventive concept but are not intended to limit the present inventive concept.

From the above analysis, it can be learned that how to identify a short-circuit fault of a sampling element of a BMS with only one sampling element and take measures to protect the BMS system is a technical problem that needs to be resolved currently.

According to characteristics of a device, the heat generated by a MOSFET or an IGBT is positively correlated with a current flowing through the MOSFET or the IGBT, and the heat is also positively correlated with the temperature rise rate. Therefore, a BMS discharge current is positively correlated with the temperature change rate of a discharge transistor. When a discharge current obtained by means of sampling cannot correspond to the temperature change rate of the discharge transistor, it can be determined that a short-circuit fault occurs to a sampling element. Details are as follows.

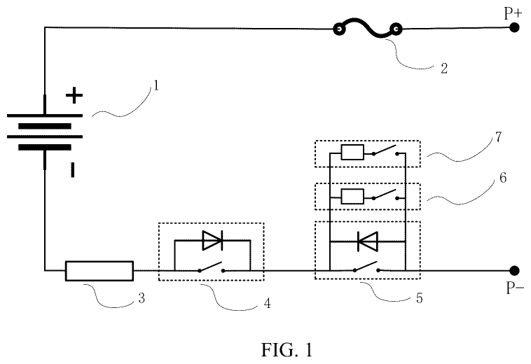

FIG. 1 is a schematic diagram of an example circuit of an existing BMS, including a battery 1, a controllable fuse 2, a sampling element 3, a discharge transistor 4, a high-current charging transistor 5, a protection charging hardware circuit and switch 6, and a float charging hardware circuit and switch 7. Whether the controllable fuse 2 is burnt out is controlled by a microcontroller unit (MCU) inside the BMS (not shown in the figure); the sampling element 3 is configured to sample charge/discharge current of the BMS; the discharge transistor 4 is composed of a metal-oxide-semiconductor field-effect transistor (MOSFET) and an anti-parallel diode included in the MOSFET, and is also controlled by the MCU to be turned on or off; the high-current charging transistor 5 is composed of a MOSFET and an anti-parallel diode included in the MOSFET, and is also controlled by the MCU to be turned on or off; the maximum charging current after the protection charging switch 6 is turned on is limited to 2 A (which may be adjusted to another value as required); and the maximum charging current after the float charging switch 7 is turned on is limited to 50 mA (which may be adjusted to another value as required). At the same time point, only one of the high-current charging transistor 5, the protection charging switch 6, and the float charging switch 7 is turned on. The turn-on described herein is equivalent to that a switch shown in FIG. 1 is closed, and there is a current flowing through the switch. In FIG. 1, P+ is a positive electrode of the BMS, and P− is a negative electrode of the BMS. In the BMS system, the discharge transistor may be one discharge transistor 4 in FIG. 1 or may be a plurality of parallel discharge transistors. To dissipate heat, a radiator (not shown in the figure) may also be disposed for the discharge transistor. To save space and costs, the radiator may not be disposed, or the plurality of discharge transistors are disposed on one radiator. Certainly, each discharge transistor may be provided with one radiator as required or as space permits.

Within a discharge current range allowed by the BMS, the inventor measures a temperature of the discharge transistor 4 when the BMS operates at different discharge currents, calculates the temperature change rate of the discharge transistor 4, and finds that different discharge currents correspond to different temperature change rates of the discharge transistor 4, and the temperature change rate of the discharge transistor 4 increases as the discharge current increases. Herein, the unit of temperature is degrees Celsius (° C.).

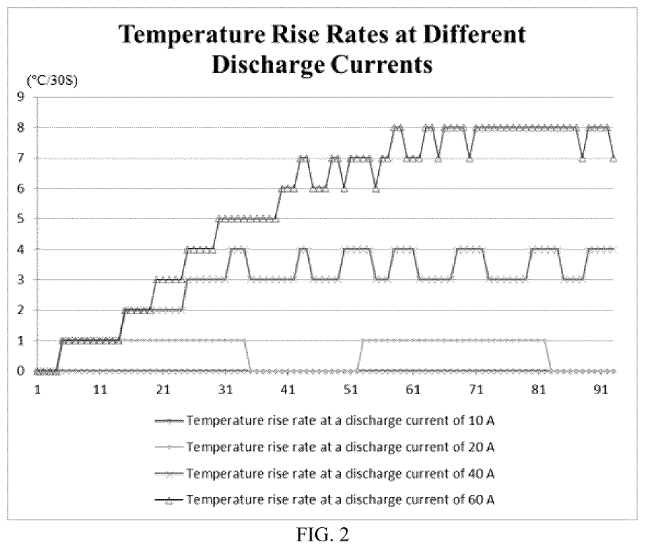

FIG. 2 shows a relationship between the temperature change rate of the discharge transistor 4 and time when the discharge current is 10 A (Amperes), 20 A, 40 A, and 60 A. The horizontal axis is the time, with the unit of second (S), and a start point of the time is four seconds before the temperature of the discharge transistor 4 changes; and the vertical axis is the temperature change rate, with the unit of ° C./30 S. A calculation method is subtracting the temperature of the discharge transistor 30 S ago from the temperature of the discharge transistor 4 at the current time point.

It can be learned from FIG. 2 that when the discharge current is 10 A, the temperature change rate of the discharge transistor 4 is 0° C./30 S, that is, the temperature of the discharge transistor 4 remains unchanged. When the discharge current is 20 A, the maximum value of the temperature change rate of the discharge transistor 4 is 1° C./30 S, that is, the temperature of the discharge transistor 4 rises by 1° C. every 30 S. When the discharge current is 40 A, the maximum value of the temperature change rate of the discharge transistor 4 is 4° C./30 S, that is, the temperature of the discharge transistor 4 rises by 4° C. every 30 S. When the discharge current is 60 A, the maximum value of the temperature change rate of the discharge transistor 4 reaches 8° C./30 S, that is, the temperature of the discharge transistor 4 rises by 8° C. every 30 S. A rule may be summarized from these data: The temperature change rate of the discharge transistor 4 is related to the discharge current. When the temperature change rate rises to a certain value, it must correspond to a relatively large discharge current. For example, when the temperature change rate is 4° C./30 S, a corresponding discharge current reaches 40 A. Therefore, if it is detected that the temperature change rate of the discharge transistor 4 is 4° C./30 S, but the discharge current obtained by the sampling element is less than 40 A, it indicates that the discharge current obtained by the sampling element is incorrect, it may be determined that the sampling element is short-circuited.

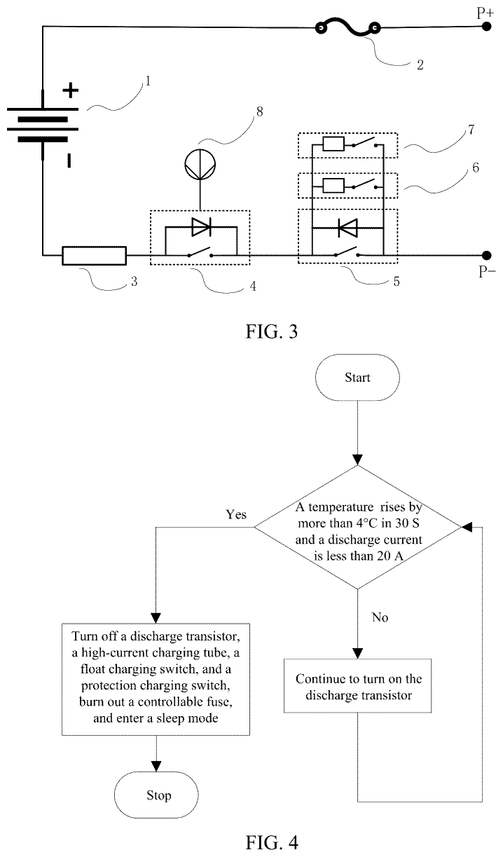

Therefore, the inventor proposes a method for identifying, based on the temperature change rate of the discharge transistor 4, whether the sampling element is short-circuited. As shown in FIG. 3, a temperature sensor 8 is disposed in the BMS system to monitor a temperature change of the discharge transistor 4. The temperature sensor 8 may be a thermocouple sensor, a thermistor sensor, a platinum resistor sensor, or the like. In some embodiments, the temperature sensor is a thermistor sensor. For example, the temperature sensor 8 may be disposed in close contact with the discharge transistor 4 or may be disposed in close contact with the radiator of the discharge transistor. Generally, the temperature sensor is communicatively connected to the microcontroller unit (MCU) (not shown in the figure) of the BMS. For example, the temperature sensor converts a collected temperature into a voltage sent to an analog-to-digital conversion (ADC) pin of the microcontroller unit (MCU) of the BMS. The MCU monitors temperature changes of the discharge transistor by using such a temperature sensor. A method for determining whether the sampling element is short-circuited is as follows: obtaining, by the temperature sensor 8, the temperature of the discharge transistor in real time, and calculating a variation difference ΔTemp between a currently obtained temperature and a temperature obtained before preset duration T (the currently obtained temperature minus the temperature obtained before the preset duration T); when the difference ΔTemp is greater than a preset temperature difference threshold Temp, comparing a discharge current obtained by a current sampling element with a preset current threshold I; and if the discharge current obtained by the current sampling element is less than the preset current threshold I, determining that the sampling element is short-circuited. For example, it may be learned from the data in FIG. 2 that, when the discharge current is 40 A, the temperature of the discharge transistor 4 rises by 4° C. every 30 S. If the temperature change in 30 S is greater than or equal to 4° C., the corresponding discharge current is greater than or equal to 40 A. If a current value obtained by means of sampling is less than 40 A, for example, is 20 A or 10 A, it may be determined that the sampling element is faulty.

Similarly, it may be learned from the data in FIG. 2 that, when the discharge current is 60 A, the temperature of the discharge transistor 4 rises by 8° C. every 30 S. If the temperature change in 30 S is greater than or equal to 8° C., the corresponding discharge current is greater than or equal to 60 A. If the current value obtained by means of sampling is less than 60 A, for example, is 40 A, 20 A, or 10 A, it may be determined that the sampling element is faulty.

Values of the preset duration T, the preset temperature difference threshold Temp, and the preset current threshold I are selected based on experimental data according to different product designs. A selection principle is that misjudgment will not be caused during normal operation of the BMS and whether the sampling element is short-circuited can be identified. In an example, the preset duration T is 30 S, the preset temperature difference threshold Temp is 4° C., and the preset current threshold I may be set to 20 A or 10 A. In another example, the preset duration T may be set to 30 S, the preset temperature difference threshold Temp is set to 8° C., and the preset current threshold I may be set to 40 A, 20 A, or 10 A.

The values of the preset duration T, the preset temperature difference threshold Temp, and the preset current threshold I are not specifically limited. For example, the preset duration may alternatively be 10 seconds or 20 seconds, and the corresponding preset temperature difference threshold Temp and the preset current threshold I are generally different. These values may be selected based on experimental data according to different product designs, provided that misjudgment will not be caused during normal operation of the BMS and whether the sampling element is short-circuited can be identified.

After detecting that the sampling element has a short-circuit fault, the BMS system needs to take measures to avoid potential troubles.

FIG. 4 is a schematic flowchart of some embodiments of protecting a BMS system after a sampling element is short-circuited. The BMS system monitors the temperature rise rate of a discharge transistor 4 and a discharge current obtained by a sampling element in real time. When it is detected that a temperature of the discharge transistor 4 rises by 4° C. within 30 seconds and the discharge current obtained by the sampling element is less than 20 A, it indicates that the sampling element is short-circuited, thereby turning off the discharge transistor 4, a high-current charging transistor 5, a float charging switch, and a protection charging switch, burning out a controllable fuse, and entering a sleep mode. Otherwise, the discharge transistor 4 continues to be turned on, and the temperature rise rate of the discharge transistor 4 and the discharge current obtained by the sampling element continue to be monitored in real time. In this embodiment, that the sampling element is short-circuited is used as a highest-level fault for processing, and when a fault occurs, the BMS disables all charging and discharging functions, burns out the controllable fuse, and enters the sleep mode. If a highest-level fault occurs, the BMS needs to be returned to the factory. According some embodiments of the present inventive concept, a condition for the foregoing protection measures to be taken by the system may further be that the temperature of the discharge transistor 4 rises by 4° C. within 30 seconds and the discharge current obtained by the sampling element is less than 10 A. According further embodiments of the present inventive concept, a condition for the foregoing protection measures to be taken by the system may further be that the temperature of the discharge transistor 4 rises by 8° C. within 30 seconds and the discharge current obtained by the sampling element is less than 40 A, 20 A, or 10 A.

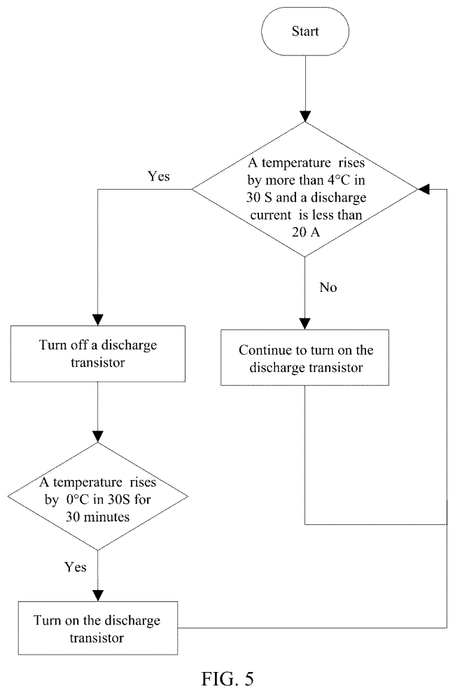

FIG. 5 is a schematic flowchart illustrating embodiments of protecting a BMS system after a sampling element is short-circuited. The BMS system monitors the temperature rise rate of a discharge transistor 4 and a discharge current obtained by a sampling element in real time. When it is detected that a temperature of the discharge transistor 4 rises by 4° C. within 30 seconds and the discharge current obtained by the sampling element is less than 20 A, it indicates that the sampling element is short-circuited, thereby turning off the discharge transistor 4. Otherwise, the discharge transistor 4 continues to be turned on, and the temperature rise rate of the discharge transistor 4 and the discharge current obtained by the sampling element continue to be monitored in real time. When the discharge transistor 4 is turned off and the temperature change rate is 0° C./30 S for 30 minutes, the discharge transistor 4 is turned on to allow another discharge. According to some embodiments of the present inventive concept, a condition for the foregoing protection measures to be taken by the system may further be that the temperature of the discharge transistor 4 rises by 4° C. within 30 seconds and the discharge current obtained by the sampling element is less than 10 A. According to some embodiments of the present inventive concept, a condition for the foregoing protection measures to be taken by the system may further be that the temperature of the discharge transistor 4 rises by 8° C. within 30 seconds and the discharge current obtained by the sampling element is less than 40 A, 20 A, or 10 A.

In the foregoing solution in which the discharge transistor 4 is turned off, and when the discharge transistor 4 is turned off and the temperature change rate is 0° C./30 S for 30 minutes, the discharge transistor 4 is turned on to allow another discharge, that the sampling element is short-circuited is used as a lower-level fault, where the lower-level fault can be recovered, and after recovery, the BMS can continue to operate.

Through the foregoing specific embodiments of the present inventive concept, a short-circuit fault of a sampling element of a BMS with only one sampling element may be identified, and measures are taken to protect the BMS system. The temperature change rate of the discharge transistor 4 is monitored by using a temperature sensor, it can be detected that the sampling element is short-circuited with reference to the discharge current obtained by the sampling element, and protection measures such as turning off the discharge transistor 4 are taken. It should be understood that the sampling element in the method described above with reference to the accompanying drawings and the embodiments may be a sampling resistor or a current sensor such as a Hall sensor. In addition, the foregoing method may be further applicable to a case in which whether an ADC (analog-to-digital converter) pin, used to collect data, a current, a voltage, and the like of a sensor, of a microcontroller unit (MCU) of, for example, a BMS system is short-circuited is identified. It should be understood that the method described above with reference to the accompanying drawings and the embodiments may be performed by the microcontroller unit (MCU) of the BMS system, or by another control module or control component that may be communicatively coupled to the MCU.

It should be noted that, in an ideal case, when the sampling element is short-circuited, sampled current data should be 0. This is because, in an ideal case, it is considered that the resistance of a short-circuit material is 0. However, in engineering practice, a sampling result after a short circuit is not necessarily 0. This is because the resistance of an actual short-circuit material generally has a certain resistance value. Therefore, sampling current data after a short circuit becomes smaller but is not necessarily reduced to 0.

Although the present inventive concept has been described by using preferred embodiments, the present inventive concept is not limited to the embodiments described herein, and includes various changes and variations without departing from the scope of the present inventive concept.

1. A short circuit identification method for a sampling element of a battery management system, wherein a temperature sensor is disposed in a battery management system to monitor a temperature of a discharge transistor, and the method comprises:
obtaining the temperature of the discharge transistor by using the temperature sensor, and calculating a temperature difference of the discharge transistor in a preset duration;
in response to determining that the temperature difference is greater than a preset temperature difference threshold, comparing a discharge current obtained by using a sampling element with a preset current threshold; and
in response to determining that the discharge current is less than the preset current threshold, determining that the sampling element is short-circuited.

2. The short circuit identification method for a sampling element of a battery management system of claim 1, wherein the temperature sensor is a thermistor.

3. The short circuit identification method for a sampling element of a battery management system of claim 1, wherein the sampling element is a sampling resistor or a Hall current sensor.

4. The short circuit identification method for a sampling element of a battery management system of claim 1, wherein the preset temperature difference threshold is 4 degrees Celsius or 8 degrees Celsius.

5. The short circuit identification method for a sampling element of a battery management system of claim 1, wherein the preset temperature difference threshold is 4 degrees Celsius, and the preset current threshold is 20 Amperes or 10 Amperes.

6. The short circuit identification method for a sampling element of a battery management system of claim 1, wherein the preset temperature difference threshold is 8 degrees Celsius, and the preset current threshold is 40 Amperes, 20 Amperes, or 10 Amperes.

7. The short circuit identification method for a sampling element of a battery management system of claim 1, wherein the preset duration is 10 seconds, 20 seconds, or 30 seconds.

8. A short circuit protection method for a sampling element of a battery management system, comprising: in response to identifying, in the short circuit identification method for a sampling element of a battery management system of claim 1, that the sampling element is short-circuited, performing circuit protection by turning off the discharge transistor of the battery management system.

9. The short circuit protection method for a sampling element of a battery management system of claim 8, wherein the circuit protection further comprises: turning off a high-current charging transistor, a float charging switch, and a protection charging switch of the battery management system, burning out a controllable fuse, and entering a sleep mode.

10. The short circuit protection method for a sampling element of a battery management system according to of claim 8, further comprising: turning on the discharge transistor in response to determining that the discharge transistor is turned off and a temperature change rate is 0 degrees Celsius every 30 S for 30 minutes.
